(19) United States
(12) Patent Application Publication
(10) Pub. No.: US 2024/0222255 A1
(43) Pub. Date: Jul. 4, 2024

(54) SEMICONDUCTOR DEVICE

(71) Applicant: POWER MASTER SEMICONDUCTOR CO., LTD., Cheongju-si (KR)

(72) Inventors: Jooyaung EOM, Gimpo-si (KR); In-Suk KIM, Bucheon-si (KR); Ki-Myung YOON, Bucheon-si (KR); Taekkeun LEE, Seoul (KR); Soonho KWON, Bucheon-si (KR)

(21) Appl. No.: 18/396,011

(22) Filed: Dec. 26, 2023

(30) Foreign Application Priority Data
Dec. 30, 2022 (KR) 10-2022-0191143
Dec. 22, 2023 (KR) 10-2023-0190216

(51) Int. Cl. H01L 23/498

(52) U.S. Cl. CPC H01L 23/49861; H01L 23/49844

(57) ABSTRACT

Provided is a semiconductor device. A semiconductor device may include: an insulated substrate whose upper surface is exposed to an outside of a molding portion; a semiconductor chip formed on a lower surface of the insulated substrate; a drain connection lead, one part of which forming a junction extending along a first direction or a second direction perpendicular to the first direction on the lower surface of the insulated substrate, and the other part of which forming a terminal that can be connected to an external device; and a source connection lead, one part of which forming an electrical connection with the semiconductor chip through a connection, and the other part of which forming a terminal that can be connected to an external device.

### CROSS-REFERENCE TO RELATED APPLICATION

This application claims priority to and the benefit of Korean Patent Application No. 10-2022-0191143 filed in the Korean Intellectual Property Office on Dec. 30, 2022, and Korean Patent Application No. 10-2023-0190216 filed in the Korean Intellectual Property Office on Dec. 22, 2023, the entire contents of which are incorporated herein by reference.

### BACKGROUND OF THE INVENTION

### (a) Field of the Invention

The present disclosure relates to a semiconductor device.

### (b) Description of the Related Art

Power semiconductor devices are semiconductor devices for transferring, controlling, and converting power, and are becoming increasingly important especially in high-power applications, like those for eco-friendly vehicles such as hybrid electric vehicles (HEVs), electric vehicles (EVs), plug-in hybrid electric vehicles (PHEVs), and fuel cell electric vehicles (FCEVs). Power semiconductor devices are required to be capable of handling high current and voltage and thus are required to have high efficiency and stability. For example, insulated gate bipolar transistors (IGBTs) are power electronics devices which have high-input impedance characteristics like metal oxide semiconductor field effect transistors (MOSFETs) and also have low conduction loss characteristics like bipolar junction transistors (BJTs), and are suitable for applications that require high switching speed while maintaining high voltage. As another example, silicon carbide (SiC) is a high-performance semiconductor material having higher electrical conductivity, higher thermal conductivity, the ability to operate devices at higher temperatures, higher voltage and current densities, higher switching speeds, as compared to silicon, and SiC semiconductors may be suitable for high-power, high-temperature, or high-frequency applications. Power semiconductor devices generate significant amounts of heat during operation, and if this heat is accumulated in the devices, it may cause serious damage. Therefore, thermal management is a critical consideration in designing power semiconductor packages, and measures for quickly and effectively dissipate heat are required. At the same time, ease of assembly may also be required when assembling with other systems or replacing products.

### SUMMARY OF THE INVENTION

The present disclosure attempts to provide a semiconductor device capable of improving the heat dissipation effect and at the same time improve assembly convenience.

A semiconductor device according to an embodiment may include: an insulated substrate whose upper surface is exposed to an outside of a molding portion; a semiconductor chip formed on a lower surface of the insulated substrate; a drain connection lead, one part of which forming a junction extending along a first direction or a second direction perpendicular to the first direction on the lower surface of the insulated substrate, and the other part of which forming a terminal that can be connected to an external device; and a source connection lead, one part of which forming an electrical connection with the semiconductor chip through a connection, and the other part of which forming a terminal that can be connected to an external device.

In some embodiments, an upper surface of the semiconductor device may be insulated from the drain connection lead.

In some embodiments, the insulated substrate may include an upper metal layer, a lower metal layer, and an insulated layer disposed between the upper metal layer and the lower metal layer, an upper surface of the upper metal layer may be exposed to an outside of the molding portion, and a lower surface of the lower metal layer may form a junction with the drain connection lead.

In some embodiments, the junction of the drain connection lead formed on a lower surface of the insulated substrate may have a shape that extends parallel to a direction in which the other part of the drain connection lead extends, or extends in a direction perpendicular to the direction in which the other part of the drain connection lead extends.

In some embodiments, an upper surface of the drain connection lead may include a plurality of upper surfaces respectively corresponding to a first height, a second height lower than the first height, and a third height lower than the second height.

In some embodiments, the drain connection lead may include a plurality of frames, the plurality of frames may include an outer frame connected to an external device; an inner frame connected to the insulated substrate; and a middle frame formed between the outer frame and the inner frame.

In some embodiments, the outer frame may be formed to extend along a first direction, and the outer frame may be formed to have a height difference from the middle frame.

In some embodiments, at least one of the inner frame may be formed to be perpendicular to the outer frame.

In some embodiments, at least one of the inner frame may be formed to be parallel to the outer frame.

In some embodiments, the inner frame may be formed integrally with the middle frame.

In some embodiments, a portion of the middle frame may be formed to have a height difference from the inner frame.

A semiconductor device according to an embodiment may include: an insulated substrate whose upper surface is exposed to an outside of a molding portion; a semiconductor chip formed on a lower surface of the insulated substrate; an outer frame connected to an external device; an inner frame connected to the insulated substrate; and a middle frame formed between the outer frame and the inner frame, wherein at least one of the middle frame extends from the other along a first direction, and then extends along a second direction perpendicular to the first direction and is connected to the inner frame.

In some embodiments, the inner frame may be formed to be perpendicular to the outer frame.

In some embodiments, at least one of the middle frame may be formed to be spaced apart from a lower surface of the insulated substrate.

In some embodiments, an upper surface of the semiconductor device may be insulated from the inner frame.

In some embodiments, the semiconductor device may further include a source connection lead, one part of which forming an electrical connection with the semiconductor chip through a connection, and the other part of which forming a terminal that can be connected to an external device.

A semiconductor device according to an embodiment may include: an insulated substrate whose upper surface is exposed to an outside of a molding portion; a semiconductor chip formed on a lower surface of the insulated substrate; an outer frame connected to an external device; an inner frame connected to the insulated substrate; and a middle frame formed between the outer frame and the inner frame, wherein at least a portion of at least one of the middle frame forms a junction with a lower surface of the insulated substrate.

In some embodiments, at least one of the inner frame may be formed to be perpendicular to the outer frame, and at least another one of the inner frame may be formed to be parallel to the outer frame.

In some embodiments, the semiconductor may further include a source connection lead, one part of which forming an electrical connection with the semiconductor chip through a connection, and the other part of which forming a terminal that can be connected to an external device.

In some embodiments, an upper surface of the semiconductor device may be insulated from the inner frame.

### BRIEF DESCRIPTION OF THE DRAWINGS

FIG. 1 to FIG. 4 are drawings for explaining a semiconductor device according to an embodiment.

FIG. 5 to FIG. 7 are drawings for explaining a semiconductor device according to an embodiment.

FIG. 8 to FIG. 10 are drawings for explaining a semiconductor device according to an embodiment.

FIG. 11 to FIG. 13 are drawings for explaining a semiconductor device according to an embodiment.

FIG. 14 to FIG. 16 are drawings for explaining a semiconductor device according to an embodiment.

### DETAILED DESCRIPTION OF THE EMBODIMENTS

Hereinafter, embodiments of the present invention will be described in detail with reference to the accompanying drawings such that those skilled in the art can easily implement them. However, the present invention can be implemented in various different forms and is not limited to the following embodiments. The drawings are to be regarded as illustrative in nature and not restrictive. Like reference numerals designate like elements throughout the specification.

Throughout the specification and the claims, unless explicitly described to the contrary, the word “comprise”, and variations such as “comprises” or “comprising”, will be understood to imply the inclusion of stated elements but not the exclusion of any other elements. Meanwhile, throughout the specification and the claims, the terms “up”, “down”, “left” and “right” are relatively defined based on the accompanying drawings only for clearly and easily explaining embodiments, and it is clear that they are not intended to limit any component to an absolute specific direction in the present invention.

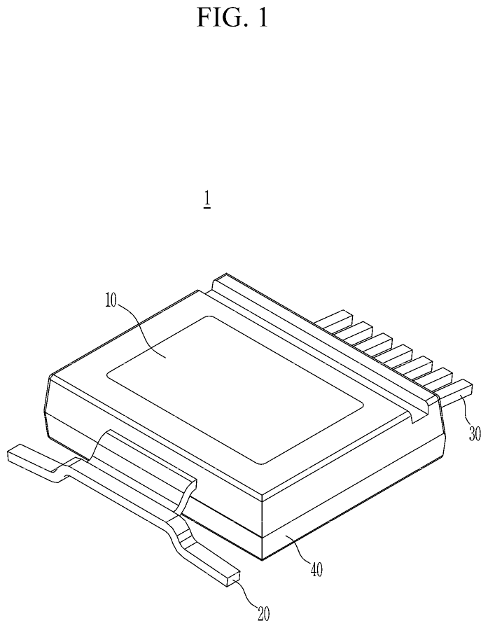

FIG. 1 to FIG. 4 are drawings for explaining a semiconductor device according to an embodiment.

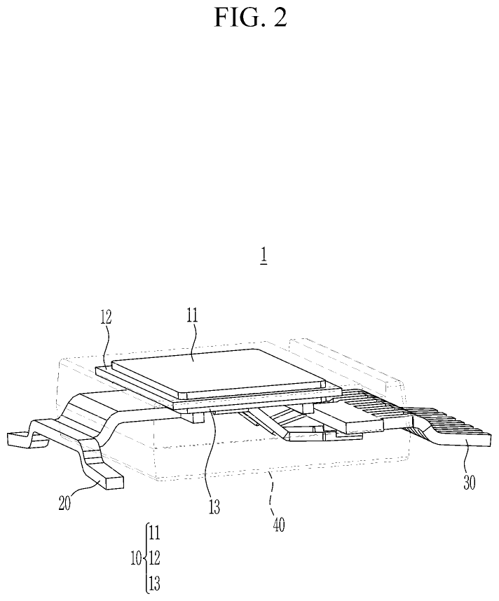

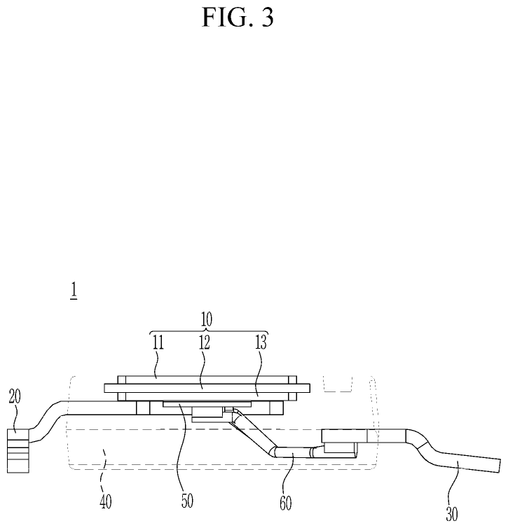

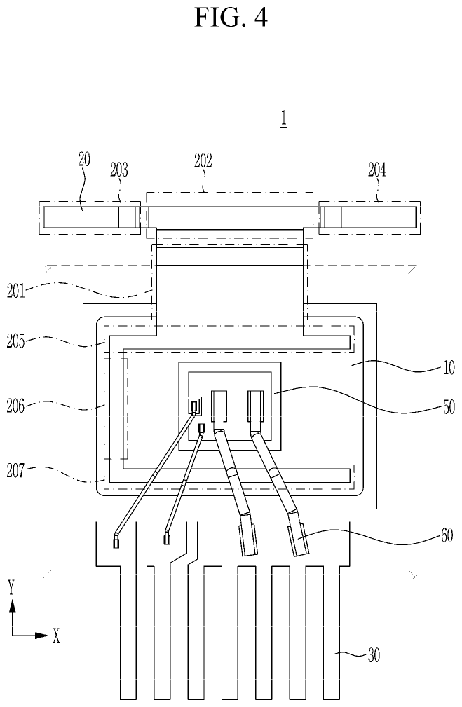

Referring to FIG. 1 to FIG. 4, a semiconductor device 1 according to an embodiment may include an insulated substrate 10, a drain connection lead 20, a source connection lead 30, a molding portion 40, and a semiconductor chip 50 and connection 60. FIG. 1 may be a perspective view of the semiconductor device 1, FIG. 2 may be a perspective view of the semiconductor device 1 showing the molding portion 40 in a dotted line, FIG. 3 may be a side view of the semiconductor device 1 showing the molding portion 40 in a dotted line, and FIG. 4 may be a rear view of the semiconductor device 1 showing the molding portion 40 in a dotted line.

The semiconductor chip 50 may be a power semiconductor device. For example, the semiconductor chip 50 may include various types of power devices such as insulated gate bipolar transistors (IGBTs) and silicon carbide (SiC) devices. Therefore, the semiconductor device 1 may be a power semiconductor device package. The semiconductor chip 50 operates under a high-power and high-voltage condition due to the nature of power semiconductor devices, and thus may generate a significant amount of heat. For clarity and convenience of description, in the drawings, one semiconductor chip 50 is shown; however, the scope of the present invention is not limited thereto. In other words, the semiconductor chip 50 may be formed of a plurality of chips depending on the specific implementation purpose, the implementation environments, and operation requirements, unlike in the drawings.

The insulated substrate 10 may absorb heat that is generated from the semiconductor chip 50 and transfer the heat to the surrounding environment of the semiconductor device 1, thereby quickly dispersing the heat, and the insulated substrate 10 may simultaneously serve as a substrate on which the semiconductor chip 50 can be mounted. The insulated substrate 10 includes an insulated layer made of an insulating material, so that the upper surface of the insulated substrate 10 may be insulated from the lower surface of the insulated substrate 10.

The upper surface of the insulated substrate 10 may be exposed to an outside of the molding portion 40. Meanwhile, a semiconductor chip 50 may be formed on the lower surface of the insulated substrate 10. Due to the insulated layer 12, the upper surface of the insulated substrate 10 and the semiconductor chip 50 may be insulated. Accordingly, the insulated substrate 10 maintains insulation from the semiconductor chip 50 and is in physical contact with the semiconductor chip 50 to absorb heat generated from the semiconductor chip 50, and then may quickly dissipate heat through the exposed upper surface to the outside of the molding portion 40. The insulated substrate 10 may be formed so as to be covered by the molding portion 40, except for the upper surface exposed to the outside. In this way, four side surfaces of the insulated substrate 10 may be covered by the molding portion 40 and only the upper surface is exposed to the outside, whereby it is possible to reduce warpage of the package while maximizing the heat dissipation area of the insulated substrate 10. Therefore, it is possible to increase the heat dissipation effect while securing the rigidity of the package. At the same time, as the upper surface of the insulated substrate 10 and the semiconductor chip 50 maintain an insulated state, when assembling the package into a vehicle system, assembly convenience can be improved by eliminating the need for additional insulating parts to insulate from the drain pad.

In some embodiments, the insulated substrate 10 may include an upper metal layer 11, an insulated layer 12, and a lower metal layer 13. The insulated layer 12 may be disposed between the upper metal layer 11 and the lower metal layer 13. The upper metal layer 11 and the lower metal layer 13 may be made of a metal with high thermal conductivity, for example copper. Meanwhile, the insulated layer 12 may be made of ceramic, for example. The upper surface of the upper metal layer 11 may be exposed to the outside of the molding portion 40, and the lower surface of the lower metal layer 13 may form a junction with the drain connection lead 20.

The drain connection lead 20 may provide a connection between the drain terminal of the semiconductor chip 50 and an external device. To this end, one part of the drain connection lead 20 may form a junction with the lower surface of the insulated substrate 10 on which the semiconductor chip 50 is mounted, and the other part of the drain connection lead 20 may form a terminal that can be connected to an external device. The drain connection lead 20 may be insulated from the top surface of the semiconductor device 1 by the insulated substrate 10 described above. The drain connection lead 20 may include various electrically conductive materials including copper, aluminum, alloys thereof, etc.

The source connection lead 30 may provide a connection between the source terminal of the semiconductor chip 50 and an external device. To this end, one part of the source connection lead 30 may form an electrical connection with the semiconductor chip 50 through the connection 60, and the other part of the source connection lead 30 may form a terminal that can be connected to an external device. The source connection lead 30 may include various electrically conductive materials including copper, aluminum, alloys thereof, etc.

The molding portion 40 may fix and protect the semiconductor chip 50 and other components mounted in the semiconductor device 1. For example, the molding portion 40 may protect the semiconductor chip 50 and other components from dust, moisture, oxidation, and other chemicals in the external environment, and fix the connection between these elements and the package. For example, the molding portion 40 may protect the semiconductor chip 50 and other components from dust, moisture, oxidation, and other chemicals in the external environment, and fix the connection between these elements and the package. Of course, the material of the molding portion 40 is not limited to the EMC, and various arbitrary materials may be used.

The connection 60 may include a wire. However, the scope of the present invention is not limited to this, and the connection 60 is a term used to include various conductive connection parts such as a clip.

In embodiments, the drain connection lead 20 may form a junction having a specially designed shape with the insulated substrates 10 so as to maximize the size of the semiconductor chip mounted under limited package size conditions. Hereinafter, the description will be made mainly with reference to FIG. 4.

The drain connection lead 20 may form a junction in which a portion of the drain connection lead 20 extends along the first direction X or the second direction Y from the lower surface of the insulated substrate 10. Here, the second direction Y may be perpendicular to the first direction X. A junction of the drain connection lead 20 formed on the lower surface of the insulated substrate 10 may extend parallel to the direction in which the other part of the drain connection lead 20 (that is, the part forming a terminal that may be connected to an external device) extends or may extend in a direction perpendicular to the direction in which the other part of the drain connection lead 20 extends.

In the present embodiment, the drain connection lead 20 may include a plurality of frames. The plurality of frames may include middle frames 201 and 202, outer frames 203 and 204, and inner frames 205, 206, and 207. The outer frames 203 and 204 may be connected to an external device, and the inner frames 205, 206, and 207 may be connected to the insulated substrate 10. The middle frames 201 and 202 may be formed between the outer frames 203 and 204 and the inner frames 205, 206, and 207. The inner frames 205, 206, and 207 may be insulated from the top surface of the semiconductor device 1 by the insulated substrate 10 described above.

The outer frames 203 and 204 may be formed to extend along the first direction X. Meanwhile, at least one 206 of the inner frames 205, 206, and 207 may be formed to be perpendicular to the outer frames 203 and 204. Additionally, at least one 205 or 207 of the inner frames 205, 206, and 207 may be formed to be parallel to the outer frames 203 and 204. That is, at least one 206 of the inner frames 205, 206, and 207 may be formed to be perpendicular to the outer frames 203 and 204, and at least another one 205 or 207 of the inner frames 205, 206, and 207 may be formed to be parallel to the outer frames 203 and 204.

The outer frames 203 and 204 may be formed to have a height difference from the middle frame 202. Meanwhile, the middle frame 202 may be formed to have a height difference from the inner frames 205, 206, and 207. That is, the outer frames 203 and 204 may be formed to have a height difference from the middle frame 202, and the middle frame 202 may be formed to have a height difference from the inner frames 205, 206, and 207, so that an upper surface of the drain connection lead 20 may include a plurality of upper surfaces respectively corresponding to a first height (that is, the height of upper surface of the inner frames 205, 206, and 207), a second height (that is, the height of upper surface of the middle frame 202) lower than the first height, and a third height (that is, the height of upper surface of the outer frames 203 and 204) lower than the second height.

In the present embodiment, at least a portion of at least one 201 of the middle frames 201 and 202 may form a junction with the lower surface of the insulated substrate 10.

According to the present embodiment, by adopting a top heat dissipation structure in which heat is dissipated from the upper part of the semiconductor device 1 and connection to the PCB is made from the lower part of the semiconductor device 1, it is easy to apply to the PCB of a vehicle system with a simplified design and has excellent thermal resistance and inductance characteristics. Additionally, by wrapping the four sides of the insulated substrate 10 with the molding portion 40 and exposing only the upper surface to the outside, it is possible to maximize the heat dissipation area of the insulated substrate 10 while reducing warpage of the package.

At the same time, by using the insulated substrate 10, the drain connection lead 20 is not directly exposed to the top surface of the semiconductor device 1, so that when assembling the semiconductor device 1 into a vehicle system, not only is there no need for additional insulating parts to insulate it from the drain connection lead 20, but even if a defect occurs in the semiconductor device 1 product, rework is easy and there is no need to replace the entire system for replacement. In addition, under the condition of the limited package size of the semiconductor device 1, a junction having a specially designed predetermined shape is formed between the drain connection lead 20 and the insulated substrate 10, so that it is possible to maximize the size of the semiconductor chip 50 that may be mounted on the semiconductor device 1. Specifically, in the present embodiment, the inner frames 205, 206, and 207 are arranged to surround the semiconductor chip 50 along directions corresponding to the three sides of the semiconductor chip 50, so that it is possible to maximize the size of the semiconductor chip mounted in a limited package size.

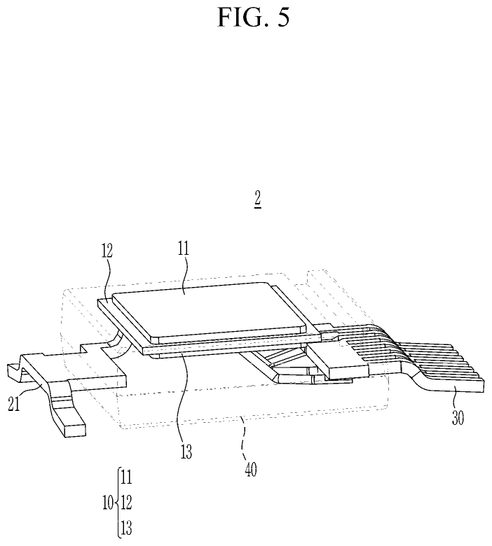

Hereinafter, various modifications related to the semiconductor device 1 will be described with reference to FIG. 5 to FIG. 16.

FIG. 5 to FIG. 7 are drawings for explaining a semiconductor device according to an embodiment.

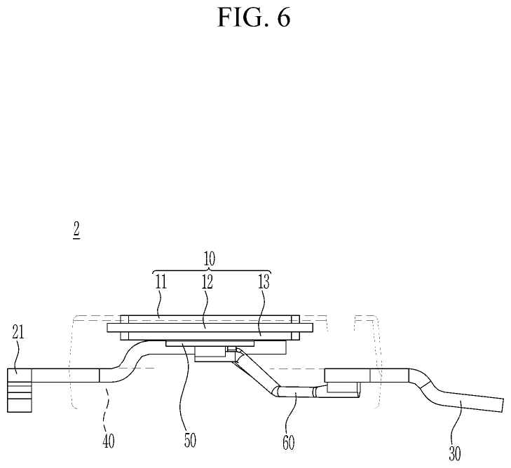

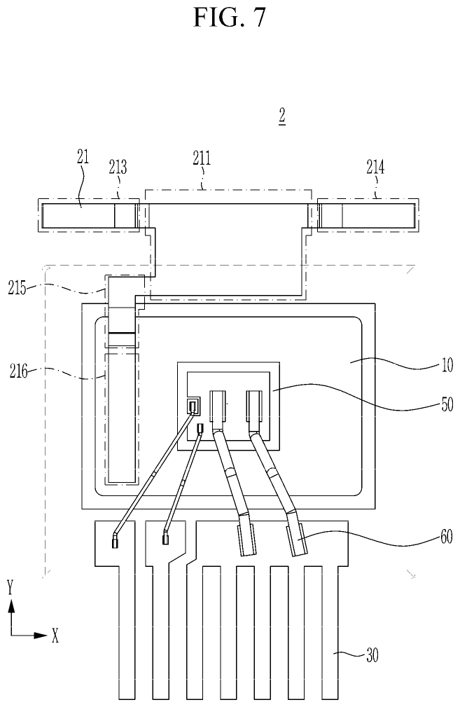

Referring to FIG. 5 to FIG. 7, a semiconductor device 2 according to an embodiment may include an insulated substrate 10, a drain connection lead 21, a source connection lead 30, a molding portion 40, and a semiconductor chip 50 and connection 60. FIG. 5 may be a perspective view of the semiconductor device 2 showing the molding portion 40 in a dotted line, FIG. 6 may be a side view of the semiconductor device 2 showing the molding portion 40 in a dotted line, and FIG. 7 may be a rear view of the semiconductor device 2 showing the molding portion 40 in a dotted line. Here, with respect to the insulated substrate 10, the source connection lead 30, the molding portion 40, the semiconductor chip 50, the previous description referring to FIG. 1 to FIG. 4 can be referred to or applied, so redundant description will be omitted here.

The drain connection lead 21 may provide a connection between the drain terminal of the semiconductor chip 50 and an external device. To this end, one part of the drain connection lead 21 may form a junction with the lower surface of the insulated substrate 10 on which the semiconductor chip 50 is mounted, and the other part of the drain connection lead 21 may form a terminal that can be connected to an external device. The drain connection lead 21 may be insulated from the top surface of the semiconductor device 2 by the insulated substrate 10 described above. The drain connection lead 21 may include various electrically conductive materials including copper, aluminum, alloys thereof, etc.

In the present embodiment, the drain connection lead 21 may form a junction having a specially designed shape with the insulated substrates 10 so as to maximize the size of the semiconductor chip mounted under limited package size conditions. Hereinafter, the description will be made mainly with reference to FIG. 7.

The drain connection lead 21 may form a junction which has a shape in which a portion extends from the lower surface of the insulated substrate 10 along the second direction Y. A junction of the drain connection lead 21 formed on the lower surface of the insulated substrate 10 may extend perpendicular to the direction in which the other part of the drain connection lead 21 (that is, the part forming a terminal that may be connected to an external device) extends.

In the present embodiment, the drain connection lead 21 may include a plurality of frames. The plurality of frames may include middle frames 211 and 215, outer frames 213 and 214, and an inner frame 216. The outer frames 213 and 214 may be connected to an external device, and the inner frame 216 may be connected to the insulated substrate 10. The middle frames 211 and 215 may be formed between the outer frames 213 and 214 and the inner frame 216. The inner frame 216 may be insulated from the top surface of the semiconductor device 2 by the insulated substrate 10 described above.

The outer frames 213 and 214 may be formed to extend along the first direction X. Meanwhile, the inner frame 216 may be formed to be perpendicular to the outer frames 213 and 214. In particular, at least one 215 of the middle frames 211 and 215 may extend from the other one 211 along the first direction X, and then extend in the second direction Y perpendicular to the first direction X to be connected to the inner frame 216. In the present embodiment, the inner frame 216 is arranged along a direction corresponding to one side of the semiconductor chip 50, thereby maximizing the size of the semiconductor chip mounted in a limited package size.

The outer frames 213 and 214 may be formed to have a height difference from the middle frame 211. Meanwhile, the middle frame 211 may be formed to have a height difference from the inner frame 216. That is, the outer frames 213 and 214 may be formed to have a height difference from the middle frame 211, and the middle frame 211 may be formed to have a height difference from the inner frame 216, so that an upper surface of the drain connection lead 21 may include a plurality of upper surfaces respectively corresponding to a first height (that is, the height of upper surface of the inner frame 216), a second height (that is, the height of upper surface of the middle frame 211) lower than the first height, and a third height (that is, the height of upper surface of the outer frames 213 and 214) lower than the second height.

In the present embodiment, at least one 211 of the middle frames 211 and 215 may be formed to be spaced apart from the lower surface of the insulated substrate 10.

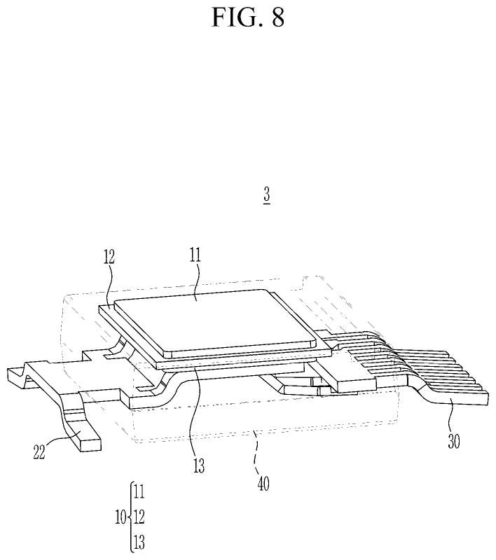

FIG. 8 to FIG. 10 are drawings for explaining a semiconductor device according to an embodiment.

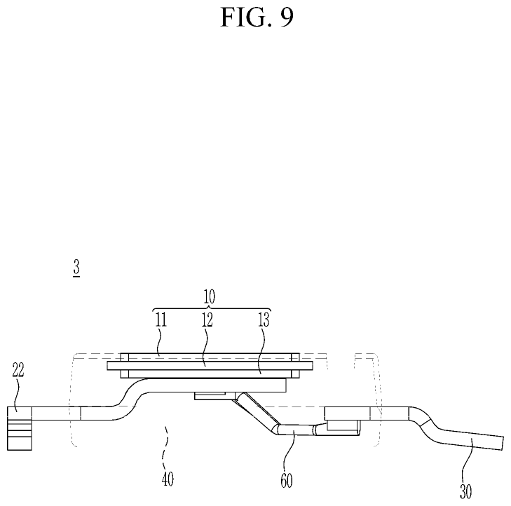

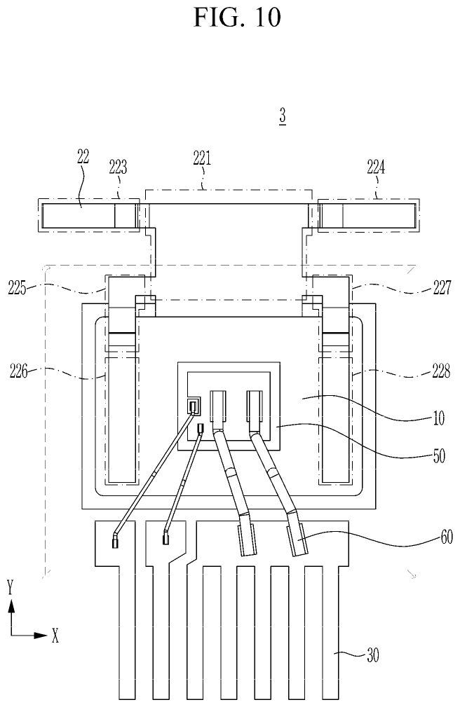

Referring to FIG. 8 to FIG. 10, a semiconductor device 3 according to an embodiment may include an insulated substrate 10, a drain connection lead 22, a source connection lead 30, a molding portion 40, and a semiconductor chip 50 and connection 60. FIG. 8 may be a perspective view of the semiconductor device 3 showing the molding portion 40 in a dotted line, FIG. 9 may be a side view of the semiconductor device 3 showing the molding portion 40 in a dotted line, and FIG. 10 may be a rear view of the semiconductor device 3 showing the molding portion 40 in a dotted line. Here, with respect to the insulated substrate 10, the source connection lead 30, the molding portion 40, the semiconductor chip 50, the previous description referring to FIG. 1 to FIG. 4 can be referred to or applied, so redundant description will be omitted here.

The drain connection lead 22 may provide a connection between the drain terminal of the semiconductor chip 50 and an external device. To this end, one part of the drain connection lead 22 may form a junction with the lower surface of the insulated substrate 10 on which the semiconductor chip 50 is mounted, and the other part of the drain connection lead 22 may form a terminal that can be connected to an external device. The drain connection lead 22 may be insulated from the top surface of the semiconductor device 3 by the insulated substrate 10 described above. The drain connection lead 22 may include various electrically conductive materials including copper, aluminum, alloys thereof, etc.

In the present embodiment, the drain connection lead 22 may form a junction having a specially designed shape with the insulated substrates 10 so as to maximize the size of the semiconductor chip mounted under limited package size conditions. Hereinafter, the description will be made mainly with reference to FIG. 10.

The drain connection lead 22 may form a junction which has a shape in which a portion extends from the lower surface of the insulated substrate 10 along the second direction Y. A junction of the drain connection lead 22 formed on the lower surface of the insulated substrate 10 may extend perpendicular to the direction in which the other part of the drain connection lead 22 (that is, the part forming a terminal that may be connected to an external device) extends.

In the present embodiment, the drain connection lead 22 may include a plurality of frames. The plurality of frames may include middle frames 221, 225, and 227, outer frames 223 and 224, and inner frames 226 and 228. The outer frames 223 and 224 may be connected to an external device, and the inner frames 226 and 228 may be connected to the insulated substrate 10. The middle frames 221, 225, and 227 may be formed between the outer frames 223 and 224 and the inner frames 226 and 228. The inner frames 226 and 228 may be insulated from the top surface of the semiconductor device 3 by the insulated substrate 10 described above.

The outer frames 223 and 224 may be formed to extend along the first direction X. Meanwhile, the inner frames 226 and 228 may be formed perpendicular to the outer frames 223 and 224. In particular, at least one 225 or 227 of the middle frames 221, 225, and 227 may extend from the other one 221 along the first direction X, and then extend in the second direction perpendicular to the first direction X to be connected to the inner frames 226 and 228. In the present embodiment, the inner frames 226 and 228 are arranged along directions corresponding to the two sides of the semiconductor chip 50, thereby maximizing the size of the semiconductor chip mounted in a limited package size.

The outer frames 223 and 224 may be formed to have a height difference from the middle frame 221. Meanwhile, the middle frame 221 may be formed to have a height difference from the inner frames 226 and 228. That is, the outer frames 223 and 224 may be formed to have a height difference from the middle frame 221, and the middle frame 221 may be formed to have a height difference from the inner frames 226 and 228, so that an upper surface of the drain connection lead 22 may include a plurality of upper surfaces respectively corresponding to a first height (that is, the height of upper surface of the inner frames 226 and 228), a second height (that is, the height of upper surface of the middle frame 221) lower than the first height, and a third height (that is, the height of upper surface of the outer frames 223 and 224) lower than the second height.

In the present embodiment, at least one 221 of the middle frames 221, 225, and 227 may be formed to be spaced apart from the lower surface of the insulated substrate 10.

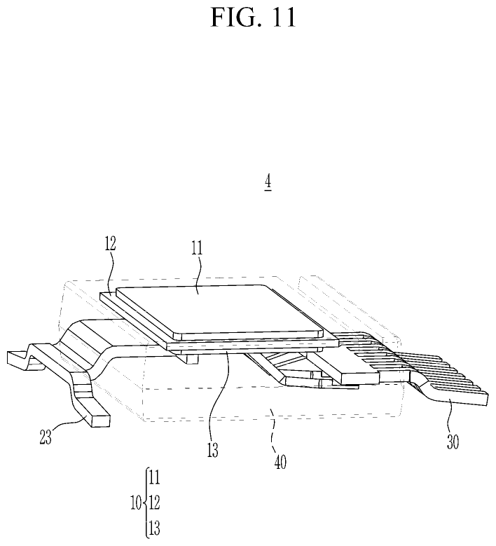

FIG. 11 to FIG. 13 are drawings for explaining a semiconductor device according to an embodiment.

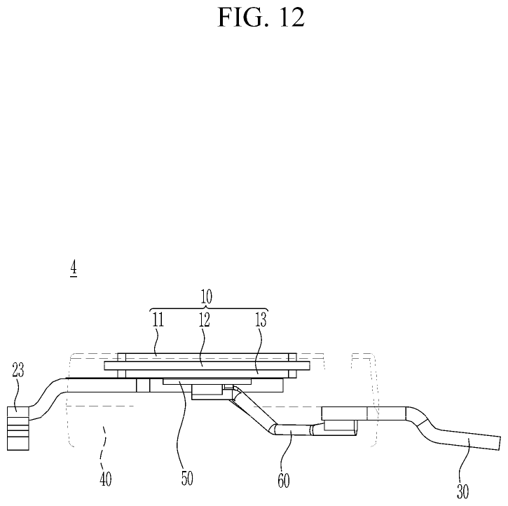

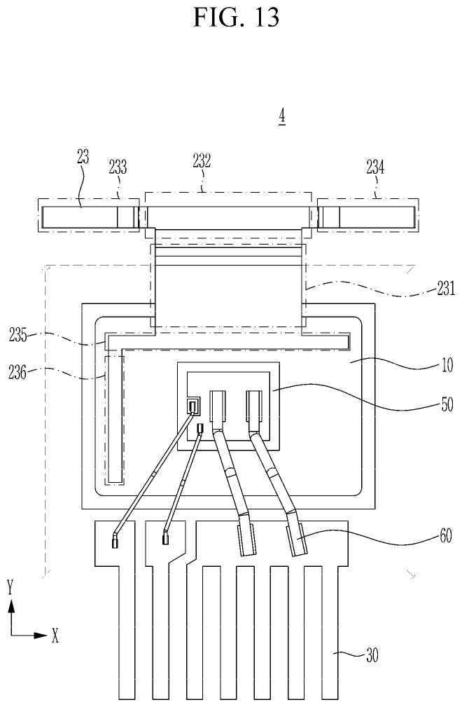

Referring to FIG. 11 to FIG. 13, a semiconductor device 4 according to an embodiment may include an insulated substrate 10, a drain connection lead 23, a source connection lead 30, a molding portion 40, and a semiconductor chip 50 and connection 60. FIG. 11 may be a perspective view of the semiconductor device 4 showing the molding portion 40 in a dotted line, FIG. 12 may be a side view of the semiconductor device 4 showing the molding portion 40 in a dotted line, and FIG. 13 may be a rear view of the semiconductor device 4 showing the molding portion 40 in a dotted line. Here, with respect to the insulated substrate 10, the source connection lead 30, the molding portion 40, the semiconductor chip 50, the previous description referring to FIG. 1 to FIG. 4 can be referred to or applied, so redundant description will be omitted here.

The drain connection lead 23 may provide a connection between the drain terminal of the semiconductor chip 50 and an external device. To this end, one part of the drain connection lead 23 may form a junction with the lower surface of the insulated substrate 10 on which the semiconductor chip 50 is mounted, and the other part of the drain connection lead 23 may form a terminal that can be connected to an external device. The drain connection lead 23 may be insulated from the top surface of the semiconductor device 4 by the insulated substrate 10 described above. The drain connection lead 23 may include various electrically conductive materials including copper, aluminum, alloys thereof, etc.

In the present embodiment, the drain connection lead 23 may form a junction having a specially designed shape with the insulated substrates 10 so as to maximize the size of the semiconductor chip mounted under limited package size conditions. Hereinafter, the description will be made mainly with reference to FIG. 13.

The drain connection lead 23 may form a junction in which a portion of the drain connection lead 23 extends along the first direction X or the second direction Y from the lower surface of the insulated substrate 10. Here, the second direction Y may be perpendicular to the first direction X. A junction of the drain connection lead 23 formed on the lower surface of the insulated substrate 10 may extend parallel to the direction in which the other part of the drain connection lead 23 (that is, the part forming a terminal that may be connected to an external device) extends or may extend in a direction perpendicular to the direction in which the other part of the drain connection lead 23 extends.

In the present embodiment, the drain connection lead 23 may include a plurality of frames. The plurality of frames may include middle frames 231 and 232, outer frames 233 and 234, and inner frames 235 and 236. The outer frames 233 and 234 may be connected to an external device, and the inner frames 235 and 236 may be connected to the insulated substrate 10. The middle frames 231 and 232 may be formed between the outer frames 233 and 234 and the inner frames 235 and 236. The inner frames 235 and 236 may be insulated from the top surface of the semiconductor device 4 by the insulated substrate 10 described above.

The outer frames 233 and 234 may be formed to extend along the first direction X. Meanwhile, at least one 236 of the inner frames 235 and 236 may be formed to be perpendicular to the outer frames 233 and 234. Additionally, at least one 235 of the inner frames 235 and 236 may be formed to be parallel to the outer frames 233 and 234. That is, at least one 236 of the inner frames 235 and 236 may be formed to be perpendicular to the outer frames 233 and 234, and at least another one 235 of the inner frames 235 and 236 may be formed to be parallel to the outer frames 233 and 234. In the present embodiment, the inner frames 235 and 236 are arranged to surround the semiconductor chip 50 along directions corresponding to the two sides of the semiconductor chip 50, thereby maximizing the size of the semiconductor chip mounted in a limited package size.

The outer frames 233 and 234 may be formed to have a height difference from the middle frame 232. Meanwhile, the middle frame 232 may be formed to have a height difference from the inner frames 235 and 236. That is, the outer frames 233 and 234 may be formed to have a height difference from the middle frame 232, and the middle frame 232 may be formed to have a height difference from the inner frames 235 and 236, so that an upper surface of the drain connection lead 23 may include a plurality of upper surfaces respectively corresponding to a first height (that is, the height of upper surface of the inner frames 235 and 236), a second height (that is, the height of upper surface of the middle frame 232) lower than the first height, and a third height (that is, the height of upper surface of the outer frames 233 and 234) lower than the second height.

In the present embodiment, at least a portion of at least one 231 of the middle frames 231 and 232 may form a junction with the lower surface of the insulated substrate 10.

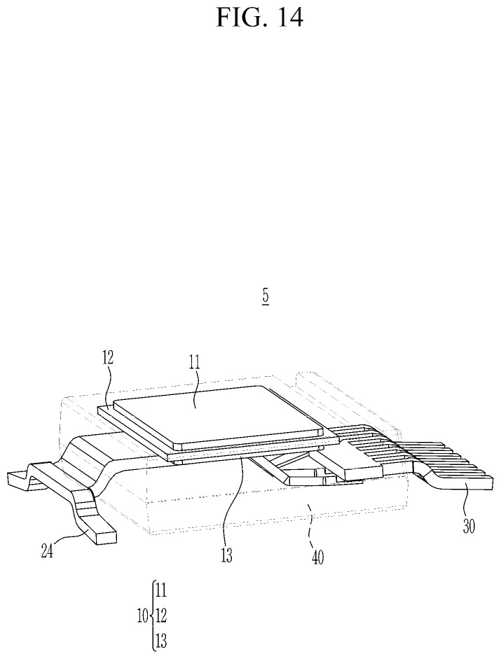

FIG. 14 to FIG. 16 are drawings for explaining a semiconductor device according to an embodiment.

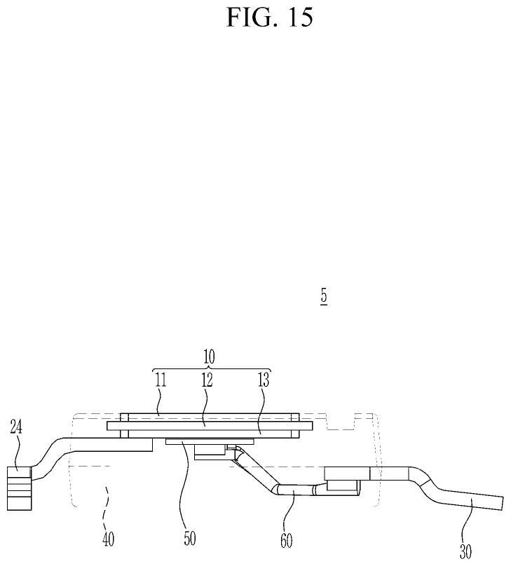

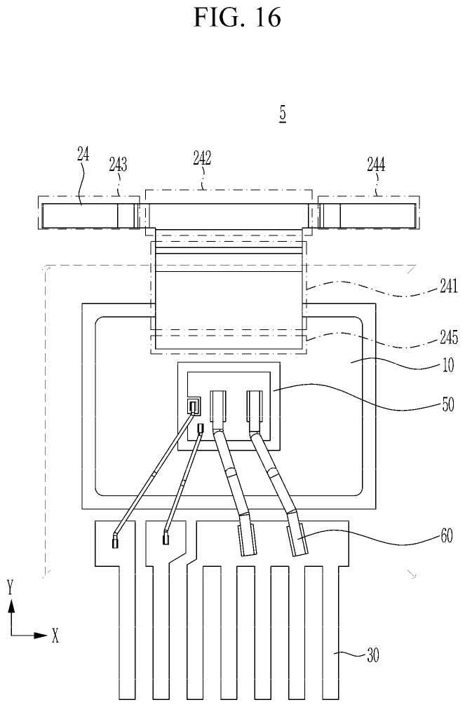

Referring to FIG. 14 to FIG. 16, a semiconductor device 5 according to an embodiment may include an insulated substrate 10, a drain connection lead 24, a source connection lead 30, a molding portion 40, and a semiconductor chip 50 and connection 60. FIG. 14 may be a perspective view of the semiconductor device 5 showing the molding portion 40 in a dotted line, FIG. 15 may be a side view of the semiconductor device 5 showing the molding portion 40 in a dotted line, and FIG. 16 may be a rear view of the semiconductor device 5 showing the molding portion 40 in a dotted line. Here, with respect to the insulated substrate 10, the source connection lead 30, the molding portion 40, the semiconductor chip 50, the previous description referring to FIG. 1 to FIG. 4 can be referred to or applied, so redundant description will be omitted here.

The drain connection lead 24 may provide a connection between the drain terminal of the semiconductor chip 50 and an external device. To this end, one part of the drain connection lead 24 may form a junction with the lower surface of the insulated substrate 10 on which the semiconductor chip 50 is mounted, and the other part of the drain connection lead 24 may form a terminal that can be connected to an external device. The drain connection lead 24 can be insulated from the top surface of the semiconductor device 5 by the insulated substrate 10 described above. The drain connection lead 24 may include various electrically conductive materials, including copper, aluminum, alloys thereof, etc.

In the present embodiment, the drain connection lead 24 may form a junction having a specially designed shape with the insulated substrates 10 so as to maximize the size of the semiconductor chip mounted under limited package size conditions. Hereinafter, the description will be made mainly with reference to FIG. 16.

The drain connection lead 24 may form a junction which has a shape in which a portion extends from the lower surface of the insulated substrate 10 along the first direction X. A junction of the drain connection lead 24 formed on the lower surface of the insulated substrate 10 may extend parallel to the direction in which the other part of the drain connection lead 24 (that is, the part forming a terminal that may be connected to an external device) extends.

In the present embodiment, the drain connection lead 24 may include a plurality of frames. The plurality of frames may include middle frames 241 and 242, outer frames 243 and 244, and an inner frame 245. The outer frames 243 and 244 may be connected to an external device, and the inner frame 245 may be connected to the insulated substrate 10. The middle frames 241 and 242 may be formed between the outer frames 243 and 244 and the inner frame 245. The inner frame 245 may be insulated from the top surface of the semiconductor device 5 by the insulated substrate 10 described above.

The outer frames 243 and 244 may be formed to extend along the first direction X. And the inner frame 245 may be formed to be parallel to the outer frames 243 and 244. In particular, the inner frame 245 may be formed integrally with the middle frames 241 and 242. In the present embodiment, the inner frame 245 is arranged along a direction corresponding to one side of the semiconductor chip 50, thereby maximizing the size of the semiconductor chip mounted in a limited package size.

The outer frames 243 and 244 may be formed to have a height difference from the middle frame 242. Meanwhile, the middle frame 242 may be formed to have a height difference from the inner frame 245. That is, the outer frames 243 and 244 may be formed to have a height difference from the middle frame 242, and the middle frame 242 may be formed to have a height difference from the inner frame 245, so that an upper surface of the drain connection lead 24 may include a plurality of upper surfaces respectively corresponding to a first height (that is, the height of upper surface of the inner frame 245), a second height (that is, the height of upper surface of the middle frame 242) lower than the first height, and a third height (that is, the height of upper surface of the outer frames 243 and 244) lower than the second height.

In the present embodiment, at least a portion of at least one 241 of the middle frames 241 and 242 may form a junction with the lower surface of the insulated substrate 10.

According to the embodiments described so far, by adopting a top heat dissipation structure in which heat is dissipated from the upper part of a semiconductor device, that is a package, and connection to the PCB is made from the lower part of the package, it is easy to apply to the PCB of a vehicle system with a simplified design and has excellent thermal resistance and inductance characteristics. At the same time, by using the insulated substrate, the drain pad is not directly exposed to the top surface of the package, so that when assembling the package into a vehicle system, not only is there no need for additional insulating parts to insulate it from the drain pad, but even if a defect occurs in the package product, rework is easy and there is no need to replace the entire system for replacement. In addition, under the condition of the limited package size, a junction having a specially designed predetermined shape is formed between the drain pad and the insulated substrate, so that it is possible to maximize the size of the semiconductor chip that may be mounted on the package. Specifically, since the internal frame is arranged along a direction corresponding to at least one side of the semiconductor chip and the remaining space can be secured, the size of the semiconductor chip mounted in a limited package size can be maximized.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
an insulated substrate whose upper surface is exposed to an outside of a molding portion;
a semiconductor chip formed on a lower surface of the insulated substrate;
a drain connection lead, one part of which forming a junction extending along a first direction or a second direction perpendicular to the first direction on the lower surface of the insulated substrate, and the other part of which forming a terminal that can be connected to an external device; and
a source connection lead, one part of which forming an electrical connection with the semiconductor chip through a connection, and the other part of which forming a terminal that can be connected to an external device.

2. The semiconductor device of claim 1, wherein:
an upper surface of the semiconductor device is insulated from the drain connection lead.

3. The semiconductor device of claim 1, wherein:
the insulated substrate includes:
an upper metal layer, a lower metal layer, and an insulated layer disposed between the upper metal layer and the lower metal layer,
an upper surface of the upper metal layer is exposed to an outside of the molding portion, and
a lower surface of the lower metal layer forms a junction with the drain connection lead.

4. The semiconductor device of claim 1, wherein:
the junction of the drain connection lead formed on a lower surface of the insulated substrate has,
a shape that extends parallel to a direction in which the other part of the drain connection lead extends, or extends in a direction perpendicular to the direction in which the other part of the drain connection lead extends.

5. The semiconductor device of claim 1, wherein:
an upper surface of the drain connection lead includes,
a plurality of upper surfaces respectively corresponding to a first height, a second height lower than the first height, and a third height lower than the second height.

6. The semiconductor device of claim 1, wherein:
the drain connection lead includes a plurality of frames,
the plurality of frames include,
an outer frame connected to an external device;
an inner frame connected to the insulated substrate; and
a middle frame formed between the outer frame and the inner frame.

7. The semiconductor device of claim 6, wherein:
the outer frame is formed to extend along a first direction, and
the outer frame is formed to have a height difference from the middle frame.

8. The semiconductor device of claim 7, wherein:
at least one of the inner frame is formed to be perpendicular to the outer frame.

9. The semiconductor device of claim 7, wherein:
at least one of the inner frame is formed to be parallel to the outer frame.

10. The semiconductor device of claim 7, wherein:
the inner frame is formed integrally with the middle frame.

11. The semiconductor device of claim 7, wherein:
a portion of the middle frame is formed to have a height difference from the inner frame.

12. A semiconductor device comprising:
an insulated substrate whose upper surface is exposed to an outside of a molding portion;
a semiconductor chip formed on a lower surface of the insulated substrate;
an outer frame connected to an external device;
an inner frame connected to the insulated substrate; and
a middle frame formed between the outer frame and the inner frame,
wherein at least one of the middle frame extends from the other along a first direction, and then extends along a second direction perpendicular to the first direction and is connected to the inner frame.

13. The semiconductor device of claim 12, wherein:
the inner frame is formed to be perpendicular to the outer frame.

14. The semiconductor device of claim 12, wherein:
at least one of the middle frame is formed to be spaced apart from a lower surface of the insulated substrate.

15. The semiconductor device of claim 12, wherein:
an upper surface of the semiconductor device is insulated from the inner frame.

16. The semiconductor device of claim 12, further comprising:
a source connection lead, one part of which forming an electrical connection with the semiconductor chip through a connection, and the other part of which forming a terminal that can be connected to an external device.

17. A semiconductor device comprising:
an insulated substrate whose upper surface is exposed to an outside of a molding portion;
a semiconductor chip formed on a lower surface of the insulated substrate;
an outer frame connected to an external device;
an inner frame connected to the insulated substrate; and
a middle frame formed between the outer frame and the inner frame,
wherein at least a portion of at least one of the middle frame forms a junction with a lower surface of the insulated substrate.

18. The semiconductor device of claim 17, wherein:
at least one of the inner frame is formed to be perpendicular to the outer frame, and
at least another one of the inner frame is formed to be parallel to the outer frame.

19. The semiconductor device of claim 17, further comprising:
a source connection lead, one part of which forming an electrical connection with the semiconductor chip through a connection, and the other part of which forming a terminal that can be connected to an external device.

20. The semiconductor device of claim 17, wherein:
an upper surface of the semiconductor device is insulated from the inner frame.
